(19) United States
(12) Patent Application Publication
(10) Pub. No.: US 2019/0305776 A1
(43) Pub. Date: Oct. 3, 2019

(54) CAPACITIVE SENSOR ELECTRODE, METHOD FOR PRODUCING A CAPACITIVE SENSOR ELECTRODE, AND CAPACITIVE SENSOR

(71) Applicant: BROSE FAHRZEUGTEILE GMBH & CO. KOMMANDITGESELLSCHAFT, BAMBERG, Bamberg (DE)

(72) Inventors: Bernd HERTHAN, Michelau (DE); Stefan HIELTSCHER, Bamberg (DE); Markus KORDER, Ebensfeld (DE); Florian POHL, Ebersdorf (DE); Thomas WEINGAERTNER, Memmelsdorf (DE)

(73) Assignee: BROSE FAHRZEUGTEILE GMBH & CO. KOMMANDITGESELLSCHA FT, BAMBERG, Bamberg (DE)

(21) Appl. No.: 16/335,449

(22) PCT Filed: Sep. 20, 2017
(86) PCT No.: PCT/EP2017/073832

§ 371 Date: Mar. 21, 2019

(30) Foreign Application Priority Data
Sep. 21, 2016 (DE) 10 2016 218 178.5

(51) Int. Cl. H03K 17/96; H03K 17/955

(52) U.S. Cl. CPC H03K 17/96; H03K 2017/9602; H03K 2217/96078; H03K 17/955

(57) ABSTRACT

A capacitive sensor electrode for a capacitive sensor, the capacitive sensor comprising an electrode wire arranged over different radial positions extending around a longitudinal axis of the wire carrier distributed in a cylinder peripheral surface of the wire carrier, and an elongated wire carrier including the electrode wire embedded in a portion of the elongated wire carrier.

### CROSS-REFERENCE TO RELATED APPLICATIONS

This application is the U.S. National Phase of PCT/EP2017/073832 filed Sep. 20, 2017, which claims priority to German Patent Application No. DE 10 2016 218 178.5 filed Sep. 21, 2016, the entire disclosures of which are incorporated by reference herein.

### TECHNICAL FIELD

The disclosure relates to a capacitive sensor electrode. Furthermore, the disclosure relates to a manufacturing method for producing such a sensor electrode. In addition, the disclosure relates to a capacitive sensor, in particular to a capacitive sensor for a motor vehicle.

### BACKGROUND

Capacitive sensors are frequently used in particular in motor vehicles in order to detect that an object is approaching the vehicle, in particular approaching a part of the vehicle. In this case, the information that is based on the detection of an approaching object is by way of example used within the scope of an anti-trap protection or anti-collision protection for vehicle parts that are moved in a motorized manner. Alternatively, such information is also used for detecting a position command of a vehicle user for a movable vehicle part, by way of example for a vehicle door, in particular for a luggage compartment flap. In particular, it is determined in the second case whether a body part of the vehicle user is moving in a predetermined manner in a sensing field that is monitored by the capacitive sensor.

During the operation for detecting the object using a first sensor electrode, the capacitive sensor generates as a sensing field a (mostly high frequency) electrical alternating field and in this case forms with a second sensor electrode (a counter-electrode) or with ground a capacitor, the capacity of which is monitored as a measuring variable. In this case, in order to form the measuring field, sensor electrodes are frequently used that have a profile (in other words cross section) that is especially tailored to suit the desired geometry of the measuring field, for example film-like conductors, round wires, etc. Frequently, a large as possible surface area radiation of the measuring field is desired, with the result that surfaces and/or material thicknesses of the aforementioned conductors or wires are increased accordingly. It is known by way of example from DE 10 2009 021 225 B4 to apply to a cable-type carrier a (hollow cylindrical) sensor electrode that surrounds said carrier.

Since metals, by way of example copper, are frequently used as material for the sensor electrodes, the weight and in particular the material costs of said sensor electrodes increases with the surface area and in particular with the material thickness of the sensor electrodes.

The object of the disclosure is to render possible a capacitive sensor that comprises a large radiation surface and nevertheless is cost-effective to produce.

This object is achieved in accordance with the disclosure by a capacitive sensor electrode having the features described below. Moreover, the object is achieved in accordance with the disclosure by a manufacturing method for a capacitive sensor electrode having the features described below. In addition, the object is achieved in accordance with the disclosure by a capacitive sensor having the features described below. Further advantageous and in part intrinsically inventive embodiments and further developments of the disclosure are disclosed in the description below.

### SUMMARY

The capacitive sensor electrode in accordance with the disclosure is used in a capacitive sensor. The sensor electrode comprises in this case an electrode wire that may be used during the operation of the sensor electrode for radiating an electrical alternating field. Furthermore, the sensor electrode comprises an elongated, for example cylindrical wire carrier, which is used to hold the electrode wire in a predetermined spatial arrangement. The electrode wire is in this case arranged over different radial positions extending around a longitudinal axis (also cylinder axis) of the wire carrier distributed in a cylinder peripheral surface of the wire carrier. In addition, the electrode wire is embedded at least in part in the wire carrier.

The term “extending distributed” is understood here and below to mean that in a viewing direction along the longitudinal axis of the wire carrier the electrode wire is arranged in at least two different “height positions” with respect to the longitudinal axis, in other words at respective different spacing with respect to the longitudinal axis and/or with respect to a plane that extends as desired through the longitudinal axis. In other words, the electrode wire is arranged extending in at least two different surface portions of the cylinder peripheral surface of the wire carrier, said surface portions being oriented in a tangential manner with respect to a longitudinal axis of the wire carrier. The term “surface portion” is to be understand in this case here and below in such a manner that also the part surface that in comparison to the entire cylinder peripheral surface is comparatively narrow (where appropriate “infinitesimal”) and that is covered by the electrode wire when said electrode wire is arranged in the cylinder peripheral surface represents such a surface portion. The term “cylinder” is to be understood here and below in such a manner that all the longitudinal lines that extend on the (cylinder) surface are formed by straight lines that are oriented parallel to the longitudinal axis. The term “cylinder” thus includes not only bodies that have a circular cross section but also includes bodies that have a polygonal or elliptical cross section. The cylinder peripheral surface represents an outer surface of the wire carrier, in other words a surface that is facing the outer face of the wire carrier. The electrode wire may be a (single) wire with a round cross section. Alternatively, the electrode wire may be formed by a (likewise twisted) braid that is composed of a multiplicity of individual wires.

The advantage of the electrode wire being arranged in accordance with the disclosure on the wire carrier renders it possible for the wire carrier (specifically the cylinder peripheral surface of said wire carrier) to be covered (also: overlapped) to a comparatively large extent in comparison to the thickness of the electrode wire with the result that with a comparatively low material outlay radiation is achieved that is comparable to that achieved using a “solid” conductor with an identical volume or identically large surface area. It is consequently possible to reduce the quantity of electrically conductive material used and thus reduce the material costs.

In one expedient embodiment, the wire carrier has a filled profile. In other words, the wire carrier is not hollow and therefore does not have in the cross section an inner-lying hollow space or the like. On the contrary, the wire carrier is “solid”. In particular, the wire carrier may be formed in this case by a solid cylinder.

In another embodiment, the electrode wire is arranged in particular in a loop-shaped manner along the wire carrier. In other words, the electrode wire is guided at least roughly in the longitudinal direction of the wire carrier at least once forward and backward with the result that an approximately U-shaped “sling” or “loop” is produced. The respective longitudinal portions of the loop extend essentially in the longitudinal direction, in other words precisely or approximately parallel to the longitudinal axis of the wire carrier. In an alternative design to the parallel orientation, the longitudinal portions are each spiraled in a helix-shaped manner, in particular in the shape of an elongated helix, about the longitudinal axis. The electrode wire may be arranged in multiple loops along the wire carrier. By virtue of guiding the electrode wire forward and backward in a loop-shaped manner, the covered area of the wire carrier is increased in a simple manner, and in particular by virtue of laying the electrode wire (in particular in multiple loops) extending about the longitudinal axis of the wire carrier, it is also possible to achieve a curved radiating surface area of the entire sensor electrode without having to use a profile of an electrically conductive semi-finished product (for example a flat conductor or a film conductor), said profile being expensive to produce in comparison to the simple, round profile of the electrode wire.

In one embodiment, the wire carrier has a polygonal profile. In other words, the cylinder peripheral surface of the wire carrier is angled multiple times and divided into multiple surface portions (also: “polygon outer surfaces”). The electrode wire is in this case arranged in particular in at least two of these polygonal outer surfaces and thus on multiple “faces” of the wire carrier. In one expedient embodiment, the wire carrier is formed from a synthetic material with the result that a polygonal profile, or rather a “square profile” renders possible a particularly simple design of a processing tool that is used during the manufacturing procedure (in other words the “mold” that is used for the injection molding process or extruding process).

In an alternative embodiment to the polygonal profile, the wire carrier has a circular cylindrical profile. The electrode wire is consequently arranged in this case when viewed in the cross section at two different radial positions on the cylinder peripheral surface (in other words or rather at a “12 o'clock position” and at a “6 o'clock position” and/or at a “3 o'clock position” or the like). The cylinder peripheral surface also represents the outer surface of the wire carrier in this case.

In one embodiment, the wire carrier is injection molded from synthetic material. In this case, the electrode wire is laid into grooves of the wire carrier, said grooves being provided in the cylinder peripheral surface in particular using injecting molding technology, (and said electrode wire is consequently embedded in the cylinder peripheral surface). In this case, the grooves render it possible in a simple manner (in particular in combination with the comparatively high creative freedom of the injection molding process) for the electrode wire to be arranged on the wire carrier in a repeatable precise manner.

In another embodiment, in particular for the event that the wire carrier is injection molded from synthetic material, the synthetic material is injection molded in part around the electrode wire (in other words the electrode wire lies open toward the environment) or the synthetic material is injection molded completely around said electrode wire. As a consequence, it is advantageously rendered possible to fix the electrode wire to the wire carrier in a particularly permanent manner (in a firmly bonded and/or positive locking manner) and also in the event that the synthetic material is injection molded completely around said electrode wire to seal the electrode wire against environmental influences. In one sub-variant, the electrode wire is in this case arranged in an intermediate step on one or multiple carrier bodies in the intended manner (in other words in particular as described above in a loop-shaped manner) and the synthetic material is subsequently injection molded around said electrode wire together with said carrier body or carrier bodies in the injection molding process, as a result of which the actual wire carrier is formed. Within the scope of the disclosure, it is therefore also conceivable that using a suitably designed injection molding tool the electrode wire is arranged in the cavity of said tool and the synthetic material of the wire carrier is subsequently injection molded around said electrode wire without the use of the carrier body or carrier bodies. However, in both cases, the electrode wire is embedded in the synthetic material of the wire carrier in a single injection molding step.

In another embodiment, in particular an alternative embodiment to the above described sub-variant, a second synthetic material component of the wire carrier is injection molded in particular in part or completely around the electrode wire. In other words, the sensor electrode is manufactured in two injection molding steps. By way of example, in this case, initially in a first injection molding step a preform (that may include the above described grooves) of the wire carrier is injection molded, subsequently the electrode wire is laid on the preform, in particular laid in the grooves of said preform, and following this in a second injection molding step the second synthetic material component is injection molded around said electrode wire. The term “second synthetic material component” is understood here and below to be the quantity of synthetic material that is injection molded into the injection molding tool in a second injection molding cycle. The synthetic material in this case is in particular the identical synthetic material of the first injection molding cycle or alternatively it is a different synthetic material, by way of example a synthetic material that is softer and/or weather-resistant in comparison to the synthetic material that is forming the preform.

In another embodiment, the electrode wire is formed by a lacquered wire, for example by a copper or steel wire that is coated with an insulating lacquer. In particular for the case that the electrode wire is embedded “only” in part in the wire carrier, it is thus rendered possible to insulate the electrode wire against environmental influences. Also for the case that the electrode wire is guided in the intended installation state with a connection portion (released from the wire carrier) to a controller of the capacitive sensor, at least this connection portion of the electrode wire is insulated with respect to the environment.

The manufacturing method in accordance with the disclosure for the sensor electrode may include the steps already mentioned above. In particular, the electrode wire may be laid in an arranging device and subsequently a synthetic material of the wire carrier is injection molded in part or completely around said electrode wire in an injection molding process.

The arranging device is in this case by way of example the described carrier body or carrier bodies or alternatively the preform of the wire carrier. In the latter case, the synthetic material is injection molded around the electrode wire by way of example in a second injection molding step of the injection molding process.

The capacitive sensor in accordance with the disclosure comprises the sensor electrode of the above described type. Furthermore, the capacitive sensor comprises an electronic control and evaluating unit that is referred to also as a controller and may be connected to the electrode wire in terms of transmitting signals.

In another embodiment, the controller is formed at least in the core by a microcontroller having a processor and a data storage device, in which the functionality with regard to controlling the sensor electrode and evaluating the signals that are received from said sensor electrode is implemented using a program in the form of an operating software (firmware). Alternatively, the controller is formed by a non-programmable electronic component, for example an ASIC, in which the aforementioned functionality is implemented using a circuit.

### BRIEF DESCRIPTION OF THE DRAWINGS

Exemplary embodiments of the disclosure are explained in detail below with the aid of a drawing. In the drawing:

FIG. 1 illustrates a schematic perspective view of a capacitive sensor having a sensor electrode and a controller, and

FIGS. 2 to 5 illustrate a schematic cross section of a respective alternative exemplary embodiment of the sensor electrode.

Mutually corresponding parts are always provided with identical reference numerals in all figures.

### DETAILED DESCRIPTION

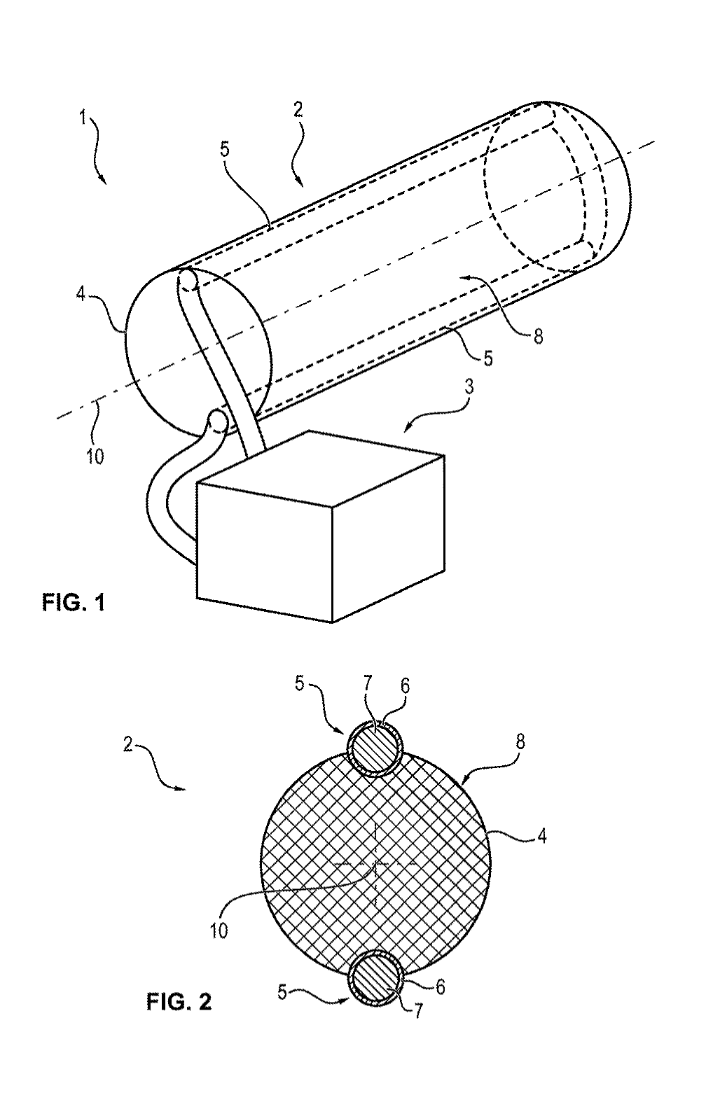

FIG. 1 illustrates a capacitive sensor 1 that is configured and provided for use in a motor vehicle. The capacitive sensor 1 comprises a capacitive sensor electrode 2 and also a controller 3 (in other words an electronic control and evaluating unit). The sensor electrode 2 is formed by an elongated, cylindrical wire carrier 4 and an electrode wire 5 that is held by the wire carrier 4. In this case, the electrode wire 5 is connected to the controller 3 in terms of transmitting signals.

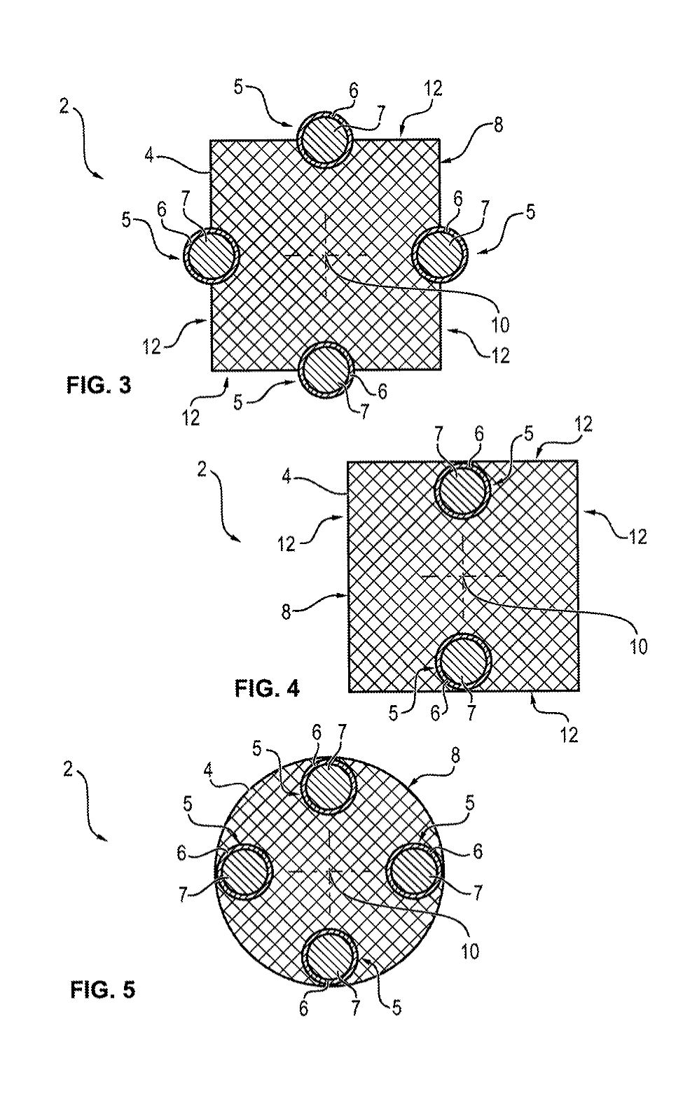

The electrode wire 5 is used during the operation of the capacitive sensor 1 so as to radiate an electrical alternating field (not illustrated in detail) into the environment of the capacitive sensor electrode 2. The electrode wire 5 is formed by a copper wire 7 that is coated with insulating lacquer 6 (cf. FIG. 2), the diameter of said wire being small in comparison to the diameter of the wire carrier 4. Nevertheless, in order to obtain a largest possible radiation surface area, the area of which is almost the size of a cylinder peripheral surface 8 of the wire carrier 4, the electrode wire 5 is laid in a loop along a longitudinal axis 10 of the wire carrier 4. In other words, the electrode wire 5 is guided forward and backward in the longitudinal direction on the wire carrier 4. In order to further increase the area covered by the electrode wire 5, the electrode wire 5 is laid in alternative exemplary embodiments (cf. FIGS. 3 and 5) in multiple loops on the wire carrier 4 and in the illustrated exemplary embodiments specifically laid in two loops. In this case, the electrode wire 5 specifically of each longitudinal portion of a loop is arranged extending around the longitudinal axis 10 distributed in a different radial position (in FIGS. 1 and 2 by way of example with regard to the finger positions of a clock at a 12 o'clock position and a 6 o'clock position).

As illustrated in FIGS. 2 and 3, the electrode wire 5 is embedded in part in the wire carrier 4. Specifically, the electrode wire 5 in these exemplary embodiments is exposed to an environment of the sensor electrode 2, such as the wire carrier 4. The wire carrier 4 is in this case injection molded with synthetic material and is provided with grooves that are complementary to the electrode wire 5, the electrode wire 5 being retrospectively laid into said grooves.

In alternative exemplary embodiments that are likewise explained with the aid of FIGS. 2 and 3, the synthetic material of the wire carrier 4 is injection molded in part around the electrode wire 5 (in a single or in a two stage injection molding process) and said electrode wire is thus held against said wire carrier in a bonded manner.

Furthermore, as is apparent from FIGS. 2 and 3 (and also from FIGS. 4 and 5), the wire carrier 4 is either configured with a circular profile (in other words as a circular cylinder) or with a polygonal profile, especially as a square. In the event of the polygonal profile, the cylinder peripheral surface 8 of the wire carrier 4 is divided into multiple mutually angled surface portions (referred to below as polygon outer surfaces 12). The electrode wire 5 extends in this case—depending upon the number of loops—in at least two of these polygon outer surfaces 12.

In one exemplary embodiment, not illustrated in detail, in order to increase the surface coverage of the electrode wire 5, multiple longitudinal portions of the electrode wire 5 are also arranged in at least one polygon outer surface 12.

As is evident from FIG. 1, the direction of the electrode wire 5 (in each case) is reversed at a longitudinal end of the wire carrier 4.

FIGS. 4 and 5 illustrate two exemplary embodiments of the sensor electrode 2, wherein the electrode wire 5 is completely embedded in the wire carrier 4. A synthetic material of the wire carrier 4 is in this case injection molded completely around the electrode wire 5 in a single stage or in a two stage injecting molding process.

In a further exemplary embodiment, not illustrated in detail, the longitudinal portions of the electrode wire 5 are spiraled in a helix-shaped manner about the longitudinal axis 10 of the wire carrier 4. In the event that the wire carrier 4 has a polygonal profile, a longitudinal portion thus extends over multiple polygon outer surfaces 12.

The subject of the disclosure is not limited to the above described exemplary embodiments. On the contrary, further embodiments of the disclosure may be derived by the person skilled in the art from the above description. In particular, the individual features of the disclosure that are described with the aid of the different exemplary embodiments and their embodiment variants may also be combined with one another in a different manner.

### LIST OF REFERENCE NUMERALS

1 Capacitive sensor
2 Capacitive sensor electrode
3 Controller
4 Wire carrier
5 Electrode wire
6 Insulating lacquer
7 Copper wire
8 Cylinder peripheral surface
10 Longitudinal axis
12 Polygon outer surface

1. A capacitive sensor electrode for a capacitive sensor,
having an electrode wire,
having an elongated wire carrier,
wherein the electrode wire is arranged over different radial positions extending around a longitudinal axis of the wire carrier distributed in a cylinder peripheral surface of the wire carrier, and
wherein the electrode wire is embedded at least in part in the wire carrier.

2. The capacitive sensor electrode as claimed in claim 1,
wherein the wire carrier has a filled profile.

3. The capacitive sensor electrode of claim 1,
wherein the electrode wire is arranged in a loop-shaped manner along the wire carrier.

4. The capacitive sensor electrode of claim 1,
wherein the wire carrier has a polygonal profile, and wherein the electrode wire is arranged in at least two polygon outer surfaces of the cylinder peripheral surface.

5. The capacitive sensor electrode of claim 1,
wherein the wire carrier has a circular cylindrical profile.

6. The capacitive sensor electrode of claim 1,
wherein the wire carrier is injection molded from synthetic material, and wherein the electrode wire is laid in grooves of the wire carrier.

7. The capacitive sensor electrode of claim 1,
wherein the wire carrier is injection molded from synthetic material, and wherein synthetic material is injection molded in part or completely around the electrode wire.

8. The capacitive sensor electrode as claimed in claim 7,
wherein a second synthetic material component of the wire carrier is injection molded around the electrode wire.

9. The capacitive sensor electrode of claim 1,
wherein the electrode wire is formed by a lacquered wire of copper or steel wire that is coated with an insulating lacquer.

10. The capacitive sensor electrode of claim 1,
wherein the electrode wire is in an arranging device and a infection molded synthetic material of the wire carrier is in part around said electrode wire.

11. The capacitive sensor electrode of claim 1 including having an electronic control and evaluating unit.

12. A capacitive sensor electrode for a capacitive sensor, the capacitive sensor comprising:
an electrode wire arranged over different radial positions extending around a longitudinal axis of the wire carrier distributed in a cylinder peripheral surface of the wire carrier; and
an elongated wire carrier including the electrode wire embedded in a portion of the elongated wire carrier.

13. The capacitive sensor of claim 12, wherein the wire carrier includes a filled profile.

14. The capacitive sensor of claim 12, wherein the electrode wire is arranged in a loop-shaped manner along the wire carrier.

15. The capacitive sensor of claim 14, wherein the electrode wire is arranged in multiple loops along the wire carrier.

16. The capacitive sensor of claim 12, wherein the wire carrier has a polygonal profile.

17. The capacitive sensor of claim 12, wherein the electrode wire is arranged in multiple carrier bodies in a loop-shaped manner with synthetic material injection molded around the electrode wire within the one or more carrier bodies.

18. The capacitive sensor of claim 12, wherein the electrode wire is a lacquered wire.

19. The capacitive sensor of claim 12, wherein the wire carrier is injection molded with synthetic material, wherein the wire carrier includes grooves complementary to the electrode wire in the grooves.

20. A capacitive sensor electrode comprising:
an electrode wire including copper wire, wherein the electrode wire is arranged over different radial positions extending around a longitudinal axis of the wire carrier in a circular peripheral surface of the wire carrier, wherein a portion of the electrode wire is exposed to an environment of the capacitive sensor electrode; and
an elongated wire carrier including the electrode wire embedded in a portion of the elongated wire carrier.
